(19) United States
(12) Patent Application Publication
(10) Pub. No.: US 2026/0079097 A1
(43) Pub. Date: Mar. 19, 2026

(54) A MEASURING UNIT

(71) Applicant: VOLVO PENTA CORPORATION, Göteborg (SE)

(72) Inventors: Viktor RÄFTEGÅRD, Floda (SE); Johan KÄLLVIK, Sollebrunn (SE)

(73) Assignee: VOLVO PENTA CORPORATION, Göteborg (SE)

(21) Appl. No.: 19/109,427

(22) PCT Filed: Sep. 7, 2023
(86) PCT No.: PCT/EP2023/074636

§ 371 Date: Mar. 6, 2025

(30) Foreign Application Priority Data
Sep. 7, 2022 (EP) 22194348.3

(51) Int. Cl. G01N 17/02; B63B 59/04; C23F 13/22; G01R 19/165; G08B 21/18

(52) U.S. Cl. CPC G01N 17/02; C23F 13/22; G01R 19/16533; G08B 21/182; B63B 59/04; C23F 2213/31

(57) ABSTRACT

A measuring unit for a target member is adapted to be submerged into a body of water. The measuring unit has a connector adapted to be in electrically conducting contact with the target member, at least a portion of the connector being in fluid communication with the environment ambient of the measuring unit; a reference electrode at least a portion of which being in fluid communication with the environment ambient of the measuring unit; a voltmeter electrically connected to each one of the connector and the reference electrode whereby the voltmeter is adapted to determine a potential difference value indicative of a potential difference between the connector and the reference electrode, and a consumer assembly adapted to consume electric energy.

### TECHNICAL FIELD

The disclosure relates generally to a measuring unit. The disclosure can be applied to a member that is adapted to be submerged into a body of water, such as a member forming part of submersed infrastructure or a seagoing vessel, for instance a boat. Although the disclosure may be described with respect to a marine vessel, the disclosure is not restricted to any particular vehicle.

### BACKGROUND

Seawater is a relatively corrosive environment and various immersed metallic parts used in marine applications such as vessels, floating structures or at least partially submerged structures require corrosion protection to avoid or minimize corrosion. A corrosion protection system is arranged to use an anode to shift the galvanic potential of the protected part or structure into a desired interval, which depends on the metallic material to be protected. There are many factors that can affect the function of a corrosion protection system, such as anode consumption, anode passivation, increased corrosion protection current demand, stray currents, etc. Hence, it is desirable to have a means for monitoring the status of the corrosion protection system and the galvanic potential currently available.

### SUMMARY

An object of the disclosure is to provide a measuring unit that can be used for evaluating the status of a corrosion protection system of a structure.

According to a first aspect of the disclosure, there is provided a measuring unit for a target member adapted to be submerged into a body of water. The measuring unit comprises:
a connector adapted to be in electrically conducting contact with the target member, at least a portion of the connector being in fluid communication with the environment ambient of the measuring unit;
a reference electrode at least a portion of which being in fluid communication with the environment ambient of the measuring unit;
a voltmeter electrically connected to each one of the connector and the reference electrode whereby the voltmeter is adapted to determine a potential difference value indicative of a potential difference between the connector and the reference electrode, and
a consumer assembly adapted to consume electric energy.
   The measuring unit further comprises an electrode member, at least a portion of the electrode member being in fluid communication with the environment ambient of the measuring unit, each one of the connector and the electrode member being electrically connected to the consumer assembly. The first aspect of the disclosure may seek to provide a measuring unit that can have the capability of feeding electric energy to the consumer assembly by virtue of the connector and the electrode member when in use. A technical benefit may include that the need for providing an additional source of electric energy, such as a battery, may be reduced.

Optionally in some examples, including in at least one preferred example, the electrode member is such that when the connector is in electrically conducting contact with the target member and when the target member and the measuring unit are submerged into a body of water, the target member and the electrode member form a galvanic cell feeding electric energy to the consumer assembly. A technical benefit may include that the target member may be used as a part for the galvanic cell feeding electric energy to the consumer assembly.

Optionally in some examples, including in at least one preferred example, the electrode member has an open circuit potential being more electropositive than a mixed potential of the target member and the connector when the connector is in electrically conducting contact with the target member. A technical benefit may include that the electrode member may act as a cathode member when feeding electric energy to the consumer assembly. The feature that the open circuit potential is more electropositive than a mixed potential of the target member and the connector when the connector is in electrically conducting contact with the target member may alternatively be formulated such that the open circuit potential is greater than a mixed potential of the target member and the connector when the connector is in electrically conducting contact with the target member, taking the signs of the open circuit potential and the mixed potential, respectively, into account.

As used here, the term “open circuit potential” of the electrode member relates to the electrode potential of the electrode member when not polarized either by being in contact with other metals or being part of an electric circuit. Generally, the “open circuit potential” is determined relative a reference electrode with a known and stable potential.

As used here, the term “mixed potential of the target member and the connector” relates to the potential of the multi-electrode formed by the target member and the connector when the connector is in electrically conducting contact with the target member.

Optionally in some examples, including in at least one preferred example, the electrode member has an open circuit potential being more electropositive than −0.5 V relative an electrode that is based on the reaction between elemental mercury and mercury chloride. A technical benefit may include that the electrode member may act as a cathode member when feeding electric energy to the consumer assembly. An electrode that is based on the reaction between elemental mercury and mercury chloride is often referred to as a saturated calomel electrode. Mercury chloride is a chemical compound with the formula Hg₂Cl₂. As such, the feature that the electrode member has an open circuit potential being more electropositive than −0.5 V relative an electrode that is based on the reaction between elemental mercury and mercury chloride may also be formulated such that the electrode member has an open circuit potential being more electropositive than −0.5 V relative a saturated calomel electrode, which may be abbreviated such that the electrode member has an open circuit potential being more electropositive than −0.5 V_{SCE}.

Optionally in some examples, including in at least one preferred example, the measuring unit further comprises a transmitter connected to the voltmeter. The transmitter is adapted to wirelessly transmit information relating to the potential difference value to a position outside the measuring unit, preferably the transmitter forms part of the consumer assembly. A technical benefit may include that information relating to the potential difference value may be transmitted without the need for wires or the like.

Optionally in some examples, including in at least one preferred example, the measuring unit further comprises a battery forming part of the consumer assembly, each one of the connector and the electrode member being electrically connected to the battery. A technical benefit may include an increased redundancy in the measuring unit since the battery may be charged by electric energy generated between the connector and the electrode member.

Optionally in some examples, including in at least one preferred example, the battery is adapted to be connected to the transmitter. A technical benefit may include an increased redundancy in the measuring unit since the battery feed electric energy to the transmitter.

Optionally in some examples, including in at least one preferred example, the connector comprises, preferably consists of, a metal or a metal alloy such as stainless steel or aluminium. A technical benefit may include that the galvanic potential of the connector is substantially the same as the galvanic potential of the target member, implying that the potential difference value indicative of a potential difference between the connector and the reference electrode is relevant also for a potential difference between the target member and the reference electrode. Preferably, the connector comprises a metal or a metal alloy that is galvanically close to the material of the target member which implies that an appropriately small potential gradient around the connector.

Optionally in some examples, including in at least one preferred example, the reference electrode comprises, preferably consists of, one of the following: zinc, a zinc alloy, silver and silver chloride. A technical benefit may include that a potential difference may be determined in a straightforward manner since the use of any one of zinc, a zinc alloy, silver and silver chloride may ensure a stable potential which generally does not vary much depending on the electrolyte.

Optionally in some examples, including in at least one preferred example, the electrode member comprises, preferably consists of, copper or a copper alloy. A technical benefit may include that the electrode member may form part of a galvanic cell feeding electric energy to the consumer assembly.

Optionally in some examples, including in at least one preferred example, the measuring unit comprises a set of additional electrode members comprising at least one additional electrode member, at least a portion of each additional electrode member in the set of additional electrode members being in fluid communication with the environment ambient of the measuring unit. A technical benefit may include an increased possibility to feed an appropriately high electric energy level to the consumer assembly.

Optionally in some examples, including in at least one preferred example, each additional electrode member in the set of additional electrode members is connected in series with the electrode member and the connector. A technical benefit may include an increased possibility to feed an appropriately high electric current level to the consumer assembly.

Optionally in some examples, including in at least one preferred example, each additional electrode member in the set of additional electrode members is such that when the connector is in electrically conducting contact with the target member and when the target member and the measuring unit are submerged into a body of water, the target member and the additional electrode member form a galvanic cell feeding electric energy to the consumer assembly. A technical benefit may include that the target member may be used as a part for the galvanic cell feeding electric energy to the consumer assembly.

Optionally in some examples, including in at least one preferred example, each additional electrode member in the set of additional electrode members has an open circuit potential being more electropositive than a mixed potential of the target member and the connector when the connector is in electrically conducting contact with the target member. A technical benefit may include that the electrode member may act as a cathode member when feeding electric energy to the consumer assembly.

Optionally in some examples, including in at least one preferred example, each additional electrode member in the set of additional electrode members has an open circuit potential being more electropositive than −0.5 V relative an electrode that is based on the reaction between elemental mercury and mercury chloride. A technical benefit may include that the electrode member may act as a cathode member when feeding electric energy to the consumer assembly.

Optionally in some examples, including in at least one preferred example, the measuring unit comprises a measuring unit body accommodating at least each one of the connector, the reference electrode, the voltmeter and the electrode member, preferably the measuring unit body is of a material having lower electric conductivity that at least each one of the connector, the reference electrode and the electrode member. A technical benefit may include that each one of the connector, the reference electrode, the voltmeter and the electrode member are kept in place in an appropriate manner.

Optionally in some examples, including in at least one preferred example, the connector comprises a connector portion adapted to be in direct contact with the target member. A technical benefit may include that the electrically conducting contact with the target member is obtained.

According to a second aspect of the disclosure, there is provided an assembly comprising a target member adapted to be submerged into a body of water and a measuring unit according to the first aspect of the disclosure, wherein the connector is in electrically conducting contact with the target member. Preferably the measuring unit is fixedly connected to the target member via the connector. The second aspect of the disclosure may seek to provide a system in which the target member may be evaluated in a straightforward manner. A technical benefit may include that the measuring unit, by virtue of being in electrically conducting contact with the target member, may provide relevant information as regards the potential difference value as well as to provide electric energy to the consumer assembly.

Optionally in some examples, including in at least one preferred example, the connector portion is in direct contact with the target member. A technical benefit may include that the electrically conducting contact with the target member is obtained.

Optionally in some examples, including in at least one preferred example, the target member is in electrically conducting contact with a sacrificial anode for corrosion protection of the target member, wherein the connector is in electrically conducting contact with the target member at a position at a distance from the sacrificial anode. A technical benefit may include that a portion of the target member that is adapted to be protected by the sacrificial anode may be assessed.

According to a third aspect of the disclosure, there is provided a marine vessel comprising the assembly according to the second aspect of the disclosure.

Optionally in some examples, including in at least one preferred example, the marine vessel comprises a monitoring unit adapted to receive measurement data from the transmitter. A technical benefit may include that the monitoring unit may receive information relating to the potential difference value associated with the target member.

Optionally in some examples, including in at least one preferred example, the monitoring unit is adapted to issue a warning signal in response to detecting that the information relating to the potential difference value is outside a predetermined range. A technical benefit may include that for instance an operator of the marine vessel may receive information relating to the potential difference value being outside a predetermined range and be able to take appropriate actions, such as inspection and/or maintenance of the target member.

According to a fourth aspect of the disclosure, there is provided a use of a measuring unit for measuring a galvanic potential value indicative of a galvanic potential of a target member adapted to be submerged into a body of water, the measuring unit comprising:
a connector adapted to be in electrically conducting contact with the target member, at least a portion of the connector being in fluid communication with the environment ambient of the measuring unit;
a reference electrode at least a portion of which being in fluid communication with the environment ambient of the measuring unit;
a voltmeter electrically connected to each one of the connector and the reference electrode whereby the voltmeter is adapted to determine a potential difference value indicative of a potential difference between the connector and the reference electrode, and
a consumer assembly adapted to consume electric energy,
   the measuring unit further comprising an electrode member, at least a portion of the electrode member being in fluid communication with the environment ambient of the measuring unit, each one of the connector and the electrode member being electrically connected to the consumer assembly.

The disclosed aspects, examples (including any preferred examples), and/or accompanying claims may be suitably combined with each other as would be apparent to anyone of ordinary skill in the art. Additional features and advantages are disclosed in the following description, claims, and drawings, and in part will be readily apparent therefrom to those skilled in the art or recognized by practicing the disclosure as described herein.

### BRIEF DESCRIPTION OF THE DRAWINGS

Examples are described in more detail below with reference to the appended drawings.

FIG. 1 is an exemplary vessel comprising a corrosion protection system according to a first example;

FIG. 2 is an exemplary vessel comprising a corrosion protection system according to a second example;

FIG. 3 is a schematic cross-section through an example of a measuring unit;

FIG. 4 is a schematic plan view of an example of a measuring unit;

FIG. 5 is a schematic plan view of an example of a measuring unit;

FIG. 6 is a schematic plan view of an example of a measuring unit;

FIG. 7 is a schematic plan view of an example of a measuring unit, and

FIG. 8 is a schematic plan view of an example of a measuring unit.

### DETAILED DESCRIPTION

The detailed description set forth below provides information and examples of the disclosed technology with sufficient detail to enable those skilled in the art to practice the disclosure.

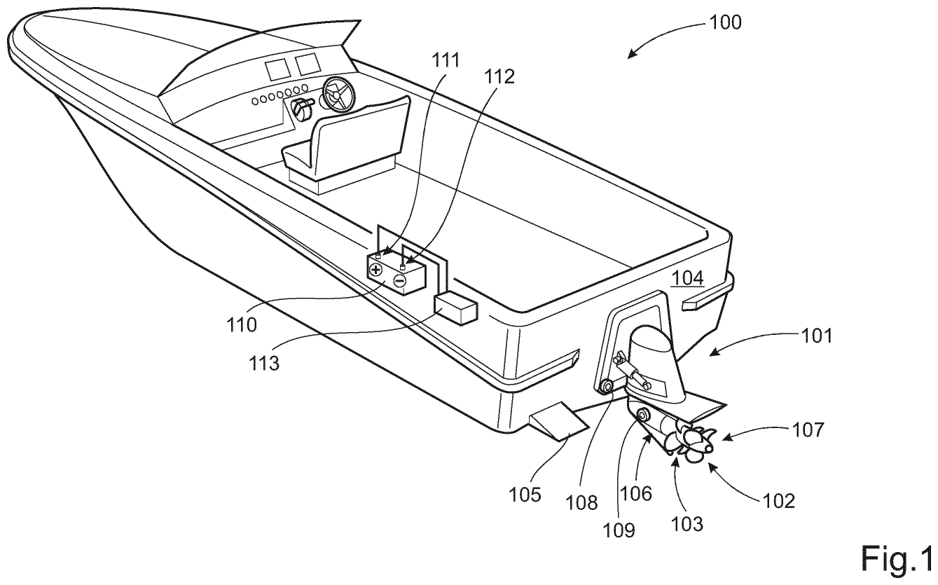

FIG. 1 shows a schematically illustrated vessel 100 comprising a corrosion protection system according to a first example. The vessel 100 comprises a hull with a transom 104 to which a marine propulsion system is attached. The propulsion system in this example comprises a single driveline housing 101 at least partially submerged in water, a torque transmitting drive shaft 106 (not shown) extending out of the driveline housing 101, and a pair of counter-rotating propellers 102, 103 mounted on the drive shaft 106. In the current example, both propellers 102, 103 are electrically isolated from its drive shaft 106. However, this is not a requirement for operation of the system. Metallic components such as the driveline housing 101, a metallic portion of the transom 104 and trim planes 105 (one shown) can be protected against corrosion using a cathodic protection arrangement. Note that this is a non-exclusive list of metallic components suitable for corrosion protection. In this example, measuring units 108, 109 are mounted on the metallic portion of the transom 104, driveline housing 101, respectively. A monitoring unit 113 (or control unit) may be adapted to receive measurement data from a transmitter (not shown) of each one of the measuring units 108, 109. Such a transmitter will be elaborated on further hereinbelow. As a non-limiting example, the vessel may comprise a battery 110 and a positive terminal 111 and a negative terminal 112 of the battery 110 may be connected to the control unit 113 in order to supply the control unit with power.

Each measuring unit 108, 109 is arranged to determine a potential difference value by means of a voltmeter as will be presented further hereinbelow. As a non-limiting example, potential difference values may be transmitted to the control unit 113 monitoring the protection potential. Measurements for the potential difference may for instance be transmitted continuously, intermittently at regular intervals or upon request from the control unit 113. This timing can be selected by the operator. In response to the received measurement data from the measuring unit 108, 109, the control unit 113 may be arranged to generate an audible and/or visual warning to an operator if it is determined that galvanic protection potential is outside the predetermined range. Transferred data can also comprise the status of a dedicated power source in a measuring unit in order to ensure that sufficient power is available to enable data transmission from the measuring unit to the control unit 113.

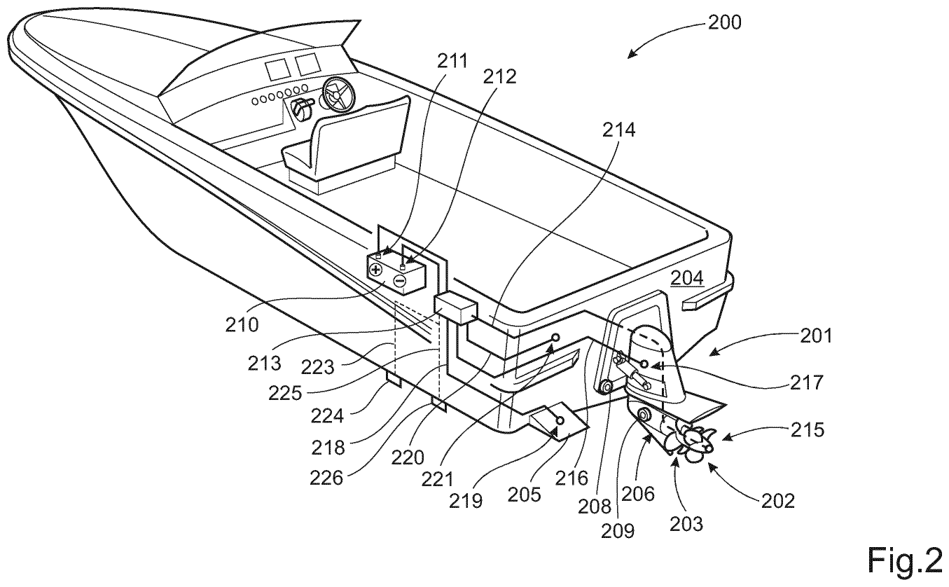

FIG. 2 shows a schematically illustrated vessel 200 comprising a corrosion protection system according to a second example. FIG. 2 illustrates the corrosion protection system and its measuring unit employed as a back-up system for an impressed current corrosion protection (ICCP) system. The vessel 200 comprises a hull with a transom 204 to which a marine propulsion system is attached. The propulsion system in this example comprises a single driveline housing 201 at least partially submerged in water, a torque transmitting drive shaft 206 (not shown) extending out of the driveline housing 201, and a pair of counter-rotating propellers 202, 203 mounted on the drive shaft 206. In the current example, both propellers 202, 203 are electrically isolated from its drive shaft 206. The drive shaft arrangement is shown in FIG. 2 and will be described in further detail below. Each electrically isolated propeller 202, 203 to be protected against corrosion is connected to a negative terminal 212 of a direct current (DC) power source 210, such as a battery, in order to form a cathode. In the same way, each additional metallic component 201, 204, 205 to be protected against corrosion is connected to a negative terminal 212 of the direct current power source 210, in order to form cathodes. An ICCP control unit 213 comprising an internal monitoring unit is connected to the direct current power source 210 and distributes current to all component parts forming an electrical circuit. The ICCP control unit 213 is arranged to regulate the voltage and current output from the direct current power source 210. In order to assist regulation of the voltage and current output a reference electrode 224 is mounted on the hull and is connected to the ICCP control unit 213 via an electrical wire 223. The reference electrode is preferable mounted remote from the protected structure in order to avoid measurement errors due to local variations in the electrical field around the protected structure. The reference electrode 224 measures a voltage difference between itself and the metallic components, which is directly related to the amount of protection received by the anode. The ICCP control unit 213 compares the voltage difference between the reference electrode 224 and the protected structure. The current output to the protected structure is then automatically adjusted by the control unit to maintain the electrode voltage equal to a pre-set voltage.

Regulation of the voltage and current output from the direct current power source is controlled to automate the current output while the voltage output is varied, or to automate the voltage output while the current output is varied. This allows the corrosion protection level to be maintained under changing conditions, e.g. variations in water resistivity, water temperature or water velocity. In a sacrificial anode system, increases in the seawater resistivity can cause a decrease in the anode output and a decrease in the amount of protection provided, while a change from stagnant conditions results in an increase in current demand to maintain the required protection level. With ICCP systems protection does not decrease in the range of standard seawater nor does it change due to moderate variations in current demand. An advantage of ICCP systems is that they can provide constant monitoring of the electrical potential at the water/protected structure interface and can adjust the output to the anodes in relation to this. An ICCP system comprising a reference electrode is more effective and reliable than sacrificial anode systems where the level of protection is unknown and uncontrollable.

The corrosion protection system in this example is an impressed current cathodic protection (ICCP) arrangement using the propellers 202, 203 as a cathode 215. In this example, hull mounted anodes (not shown) connected to the positive terminal 211 are used.

In FIG. 2, the metallic component to be protected against corrosion is the driveline housing 201, the trim tabs 205 (one shown), and a metal portion of the hull, in this case the transom 204. Note that this is a non-exclusive list of metallic components suitable for corrosion protection. In order to achieve this, the positive terminal 211 and the negative terminal 212 of the battery 210 are connected to the ICCP control unit 213. The ICCP control unit 213 is arranged to connect the negative terminal 212 to the propellers 202, 203 via a first electrical wire 214. The ICCP control unit 213 is further arranged to connect the negative terminal 212 to an electrical connector 217 on the driveline housing 201 via a second electrical wire 216. The negative terminal 212 is also connected to an electrical connector 219 on the trim tab 205 via a third electrical wire 218 and is connected to an electrical connector 221 on the transom 204 via a fourth electrical wire 220. The corrosion protection system is further provided with a passive, sacrificial anode 226 that can provide protection if a failure occurs in the active anti-fouling arrangement. The sacrificial anode 226 can be located at any suitable location on the vessel and is connectable to the ICCP control unit 213 via a fifth electrical wire 225.

The corrosion protection system in this example can be provided with at least one measuring unit 208, 209 arranged to communicate with the internal monitoring unit in the ICCP control unit 213. Each measuring unit 208, 209 may be adapted to determine a potential difference value using a voltmeter as will be elaborated on further hereinbelow. Information relating to such a potential difference value may be transmitted to the ICCP control unit 213. Measurements for the potential difference can be transmitted continuously, intermittently at regular intervals or upon request from the ICCP control unit 213. In response to the received measurement data from the measuring units 208, 209, the ICCP control unit 213 may be arranged to generate an audible and/or visual warning to an operator if it is determined that galvanic protection potential is outside the predetermined range. Transferred data can also comprise the status of a dedicated power source in the measuring unit in order to ensure that sufficient power is available to enable data transmission from the measuring unit to the control unit.

It should be noted that the metallic components such as the driveline housing 101, a metallic portion of the transom 104 and trim planes 105 (one shown) of the FIG. 1 as well as each one of the components 201, 202, 203, 204, 205 presented hereinabove in relation to FIG. 2 may serve as an example of a target member that is adapted to be submerged into a body of water. However, it is also envisaged that the target member adapted to be submerged into a body of water may also form part of another entity, such as an at least partially submerged structure, for instance an offshore structure (not show), a bridge (not shown) or a subsea structure (not shown). Irrespective of the example of the target member, it may be desired to gain information about a galvanic potential of the target member. Purely by way of example, if the target member is protected by a corrosion protection system arranged to use an anode to shift the galvanic potential of the target member into a desired range, which depends on the metallic material to be protected, it may be desired to determine information about the galvanic potential in order to assess whether or not the corrosion protection system is operating as intended.

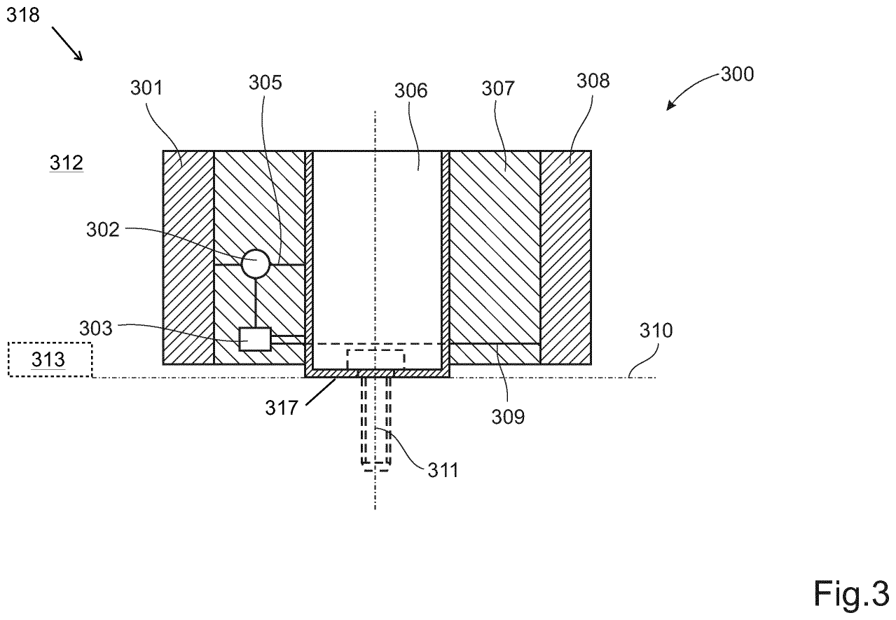

To this end, reference is made to FIG. 3 illustrating an example of a measuring unit 300 for a target member 310 adapted to be submerged into a body of water 312. As indicated above, the target member 310 may for instance form part of any one of the above listed examples.

The measuring unit 300 comprises:
a connector 306 adapted to be in electrically conducting contact with the target member 310, at least a portion of the connector being in fluid communication with the environment ambient of the measuring unit 300;
a reference electrode 301 at least a portion of which being in fluid communication with the environment ambient of the measuring unit 300;
a voltmeter 302 electrically connected to each one of the connector 306 and the reference electrode 301 whereby the voltmeter 302 is adapted to determine a potential difference value indicative of a potential difference between the connector 306 and the reference electrode 301, and
a consumer assembly 303 adapted to consume electric energy.

By means of the above-mentioned potential difference value, it may be possible to determine information indicative of the galvanic potential of the target member 310. As a non-limiting example, if the target member 310 is protected by a corrosion protection system arranged to use an anode 313 to shift the galvanic potential of the target member 310 into a desired range, the potential difference value may provide information indicative of whether or not the corrosion protection system is operating as intended. Here, it should be noted that if e.g. the open circuit potential of the reference electrode 301 is known, it is possible to determine the galvanic potential of the target member 310 using the above-mentioned potential difference value.

Moreover, as a non-limiting example, the measuring unit 300 may be arranged to be fixed to and be in electrically conducting contact with the target member 310 via the connector 306. As schematically exemplified in FIG. 3, a suitable fastener such as a threaded screw 311 may be passed through an opening in the connector 306 and fixed into a corresponding threaded opening (not shown in FIG. 3) in the target member 310.

Purely by way of example, the connector 306 comprises, preferably consists of, a metal or a metal alloy such as stainless steel or aluminium.

Purely by way of example, the reference electrode 301 comprises, preferably consists of, one of the following: zinc, a zinc alloy, silver and silver chloride.

The measuring unit 300 further comprises an electrode member 308. At least a portion of the electrode member 308 is in fluid communication with the environment ambient of the measuring unit 300. Each one of the connector 306 and the electrode member 308 is electrically connected to the consumer assembly 303.

Optionally in some examples, including in at least one preferred example, the electrode member comprises, preferably consists of, copper or a copper alloy.

The consumer assembly 303 may be implemented in a plurality of different ways as will be elaborated on hereinbelow. Moreover, though purely by way of example, as indicated in FIG. 3, the measuring unit 300 may comprise a measuring unit body 307 accommodating at least each one of the connector 306, the reference electrode 301, the voltmeter 302 and the electrode member 308. As a non-limiting example, the measuring unit body 307 is of a material having lower electric conductivity than at least each one of the connector 306, the reference electrode 301 and the electrode member 308. Purely by way of example, the measuring unit body 307 may comprise, or even be constituted by, a plastics material.

In the FIG. 3 example, the measuring unit 300 has a substantially cylindrical shape. However, it is envisaged that other example of the measuring unit 300 may have other shapes.

Moreover, the measuring unit 300 of the present disclosure may have the capability of feeding electric energy to the consumer assembly 303 by virtue of the connector 306 and the electrode member 308 when in use. To this end, though purely by way of example, as may be gleaned from FIG. 3, the electrode member 308 is such that when the connector 306 is in electrically conducting contact with the target member 310 and when the target member 310 and the measuring unit 300 are submerged into a body of water 312, the target member 310 and the electrode member 308 form a galvanic cell feeding electric energy to the consumer assembly 303.

Put differently, the electrode member 308 is such that when the connector 306 is in electrically conducting contact with the target member 310 and when the target member 310 and the measuring unit 300 are submerged into a body of water 312, an electromotive force is created by an electrolytic reaction between the connector 306 connected to the target member 310 and the electrode member 308 of the measuring unit 300 where the surrounding body of water 312 (which preferably is a body of seawater) is arranged to act as an electrolyte. The electrochemical energy supplied by this source of energy can be fed to the consumer assembly 303.

As a non-limiting example, the electrode member 308 may have an open circuit potential being more electropositive than a mixed potential of the target member 310 and the connector 306 when the connector 306 is in electrically conducting contact with the target member 310.

As a non-limiting example, the electrode member 308 has an open circuit potential being more electropositive than −0.5 V relative an electrode (not shown) based on the reaction between elemental mercury and mercury chloride. An electrode that is based on the reaction between elemental mercury and mercury chloride is often referred to as a saturated calomel electrode. As such, the feature that the electrode member 308 has an open circuit potential being more electropositive than −0.5 V relative an electrode that is based on the reaction between elemental mercury and mercury chloride may also be formulated such that the electrode member 308 has an open circuit potential being more electropositive than −0.5 V relative a saturated calomel electrode, which may be abbreviated such that the electrode member 308 has an open circuit potential being more electropositive than −0.5 V_{SCE}.

As such, the open circuit potential of the electrode member 308 may be determined using the electrode member 308 and the above-mentioned saturated calomel electrode (not shown). For the sake of completeness, it should be noted that the saturated calomel electrode (not shown) need not form part of the measuring unit 300 and generally does not form part of the measuring unit 300. Consequently, the feature that the electrode member 308 has an open circuit potential being more electropositive than −0.5 V relative an electrode that is based on the reaction between elemental mercury and mercury chloride may alternatively be formulated such that the electrode member 308 has an open circuit potential being more electropositive than −0.5 V when determined relative an electrode that is based on the reaction between elemental mercury and mercury chloride. The above alternative may be applicable to any example of the present disclosure. Alternatively, the feature that the electrode member 308 has an open circuit potential being more electropositive than −0.5 V relative an electrode that is based on the reaction between elemental mercury and mercury chloride may be formulated such that the electrode member 308 has an open circuit potential being more electropositive than −0.5 V when determined relative a saturated calomel electrode, which again may be abbreviated such that the electrode member 308 has an open circuit potential being more electropositive than −0.5 V_{SCE}. The above alternative may be applicable to any example of the present disclosure.

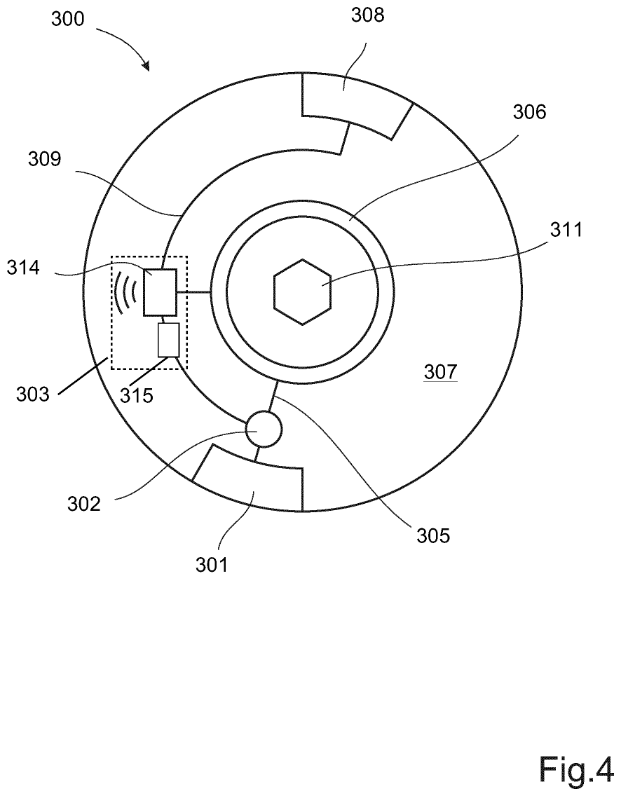

FIG. 4 illustrates a top cross-sectional view of an example of a measuring unit 300 in which the measuring unit 300 further comprises a transmitter 314 connected to the voltmeter 302. The transmitter 314 is adapted to wirelessly transmit information relating to the potential difference value to a position outside the measuring unit 300. Purely by way of example, the transmitter 314 may form part of, or for example constitute, the consumer assembly 303. Moreover, the FIG. 4 example illustrates that each one of the electrode member 308 and the connector 306 may be connected to the consumer assembly 303 by means of an electrically conductive member 309, such as a wire.

As also indicated in the FIG. 4 example, the measuring unit 300 may comprise a battery 315 forming part of the consumer assembly 303. As a non-limiting example, each one of the connector 306 and the electrode member 308 may be electrically connected to the battery 315. As a non-limiting example, and as indicated in FIG. 4, the battery 315 may be adapted to be connected to the transmitter 314. Again purely by way of example, the battery 315 may be adapted to feed electric energy to the transmitter 314.

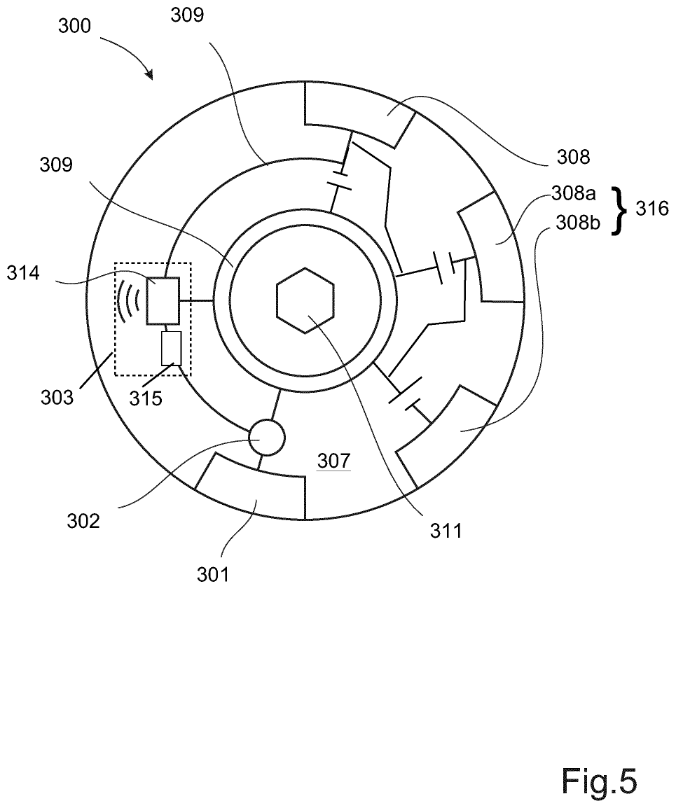

It should be noted that the measuring unit 300 need not contain only one electrode member 308. To this end, reference is made FIG. 5 illustrating an example of the measuring unit 300 which comprises a set of additional electrode members 316 comprising at least one additional electrode member 308a, 308b. At least a portion of each additional electrode member 308a, 308b in the set of additional electrode members 316 is in fluid communication with the environment ambient of the measuring unit 300. Purely by way of example and as schematically exemplified in FIG. 5, each additional electrode member 308a, 308b in the set of additional electrode members 316 is connected in series with the electrode member 308 and the connector 306.

As a non-limiting example, each additional electrode member 308a, 308b in the set of additional electrode members 316 is such that when the connector 306 is in electrically conducting contact with the target member 310 and when the target member 310 and the measuring unit 300 are submerged into a body of water 312, the target member 310 and the additional electrode member 308a, 308b form a galvanic cell feeding electric energy to the consumer assembly 303.

Purely by way of example, each additional electrode member 308a, 308b in the set of additional electrode members 316 has an open circuit potential being more electropositive than a mixed potential of the target member 310 and the connector 306 when the connector is in electrically conducting contact with the target member 310.

As a non-limiting example, each additional electrode member 308a, 308b in the set of additional electrode members 316 has an open circuit potential being more electropositive than −0.5 V relative an electrode that is based on the reaction between elemental mercury and mercury chloride.

Reverting to the FIG. 3 example, it may be noted therefrom that the connector 306 may comprise a connector portion 317 adapted to be in direct contact with the target member 310. Purely by way of example, and as illustrated in FIG. 3, the connector 306 may for instance comprise a socket, such as a cylindrical socket, and the connector portion 317 may form a bottom portion of such a socket.

Moreover, FIG. 3 also illustrates an example of a second aspect of the present disclosure which relates to an assembly 318 comprising a target member 310 adapted to be submerged into a body of water and a measuring unit 300 according to the first aspect of the present disclosure. In the second aspect of the disclosure and as indicated in FIG. 3, the connector 306 is in electrically conducting contact with the target member 310. Preferably the measuring unit 300 is fixedly connected to the target member 310 via the connector 306 such as via the above-mentioned threaded screw 311.

Purely by way of example, as also indicated in FIG. 3, the connector portion 317 may be in direct contact with the target member 310.

As a non-limiting example, the target member 310 may be in electrically conducting contact with a sacrificial anode 313 for corrosion protection of the target member 310. The connector 306 may be electrically conducting contact with the target member 306 at a position at a distance from the sacrificial anode 313.

A third aspect of the disclosure relates to a marine vessel 100; 200 comprising the assembly 318 according the second aspect of the disclosure. To this end, references are made to FIG. 1 and FIG. 2. As such, the target member 310 may form part of a marine vessel 100; 200.

The marine vessel 100; 200 may comprise a monitoring unit 113; 213 adapted to receive measurement data from the transmitter 314. By way of example only, the monitoring unit 113; 213 may be adapted to issue a warning signal in response to detecting that the information relating to the potential difference value is outside a predetermined range.

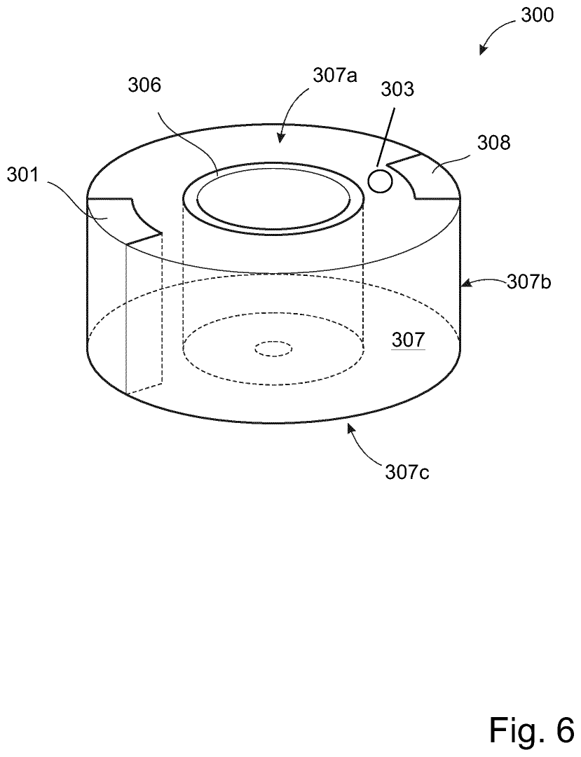

FIG. 6 illustrates a schematic perspective view of an example of a measuring unit 300. The measuring unit 300 comprises a measuring unit body 307, a connector 306 and a reference electrode 301 mounted to the measuring unit body 307 separated from and in electrical connection with the connector 306. The measuring unit body 307 comprises an upper annular surface 307a, a lower annular surface 307c and a cylindrical side surface 307b connecting the upper and lower surfaces 307a, 307c.

The example in FIG. 6 comprises an electrode member 308 separated from and in electrical connection with the connector 306 via a consumer assembly 303. An electromotive force is created by an electrolytic reaction between the connector 306 connected to a target member (not shown in FIG. 6) and in electrical connection with the electrode member 308 mounted to the body 307 of the measuring unit 300 and where surrounding seawater is arranged to act as an electrolyte.

In the FIG. 6 example, the reference electrode 301 and the electrode member 308 are moulded into the measuring unit body 307 and extending from the upper surface 307a to the lower surface 307c. Both the reference electrode 301 and the electrode member 308 have exposed surfaces at both ends and along their outer surfaces which interrupt the cylindrical side surface 307b. When immersed, the reference electrode 301 and the electrode member 308 will be exposed to seawater on three sides. When mounted, the lower ends of the reference electrode 701 and the electrode member 308 should preferably be kept out of contact with the target member (not shown in FIG. 6).

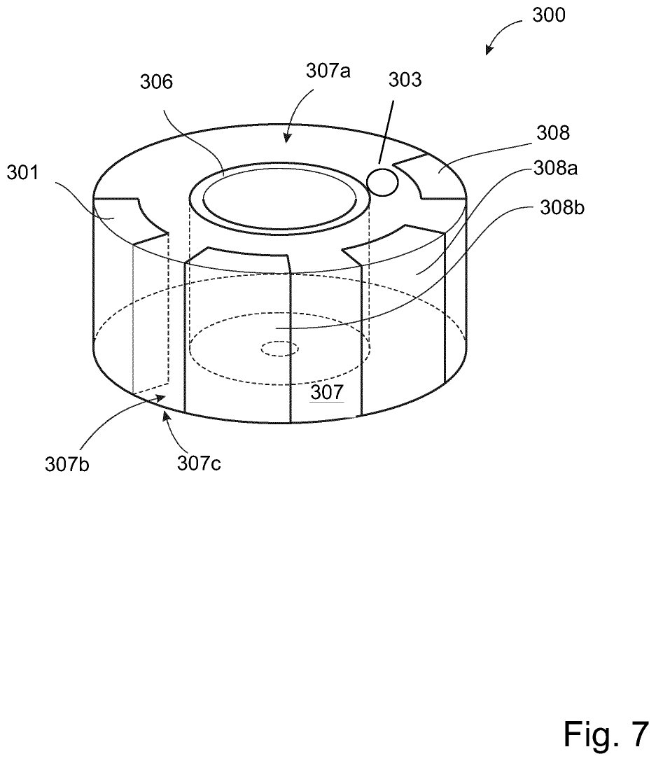

FIG. 7 illustrates a schematic perspective view of another example of the measuring unit 300. The measuring unit 300 comprises a measuring unit body 307 which for instance may comprise an electrically insulating material, a connector 306 for fixing the measuring unit 300 in direct electrical contact with a target member (not shown in FIG. 7) and a reference electrode 301 mounted to the measuring unit body 307 separated from and in electrical connection with the connector 306. The measuring unit body 307 comprises an upper annular surface 307a, a lower annular surface 307c and a cylindrical side surface 307b connecting the upper and lower surfaces 307a, 307c.

The example illustrated in FIG. 7 comprises an electrode member 308 and additional electrode members 308a, 308b mounted to the measuring unit body 307 separated from and in electrical connection with the connector 306 via a consumer assembly 303. An electromotive force is created by an electrolytic reaction between the connector 306 connected to the target member (not shown in FIG. 7) and in electrical connection with the electrode member 308 and additional electrode members 308a, 308b mounted to the measuring unit body 307 of the measuring unit 300 and where surrounding seawater is arranged to act as an electrolyte.

In the example illustrated in FIG. 7, the reference electrode 301, the electrode member 308 and additional electrode members 308a, 308b are moulded into the measuring unit body 307 and extending from the upper surface 307a to the lower surface 307c. Each one of the reference electrode 301, the electrode member 308 and additional electrode members 308a, 308b has exposed surfaces at both ends and along their outer surfaces which interrupt the cylindrical side surface 307b. When immersed, the reference electrode 301, the electrode member 308 and additional electrode members 308a, 308b will be exposed to seawater on three sides. When mounted the lower ends of the reference electrode 301, the electrode member 308 and additional electrode members 308a, 308b should preferably be kept out of contact with the target member (not shown in FIG. 7).

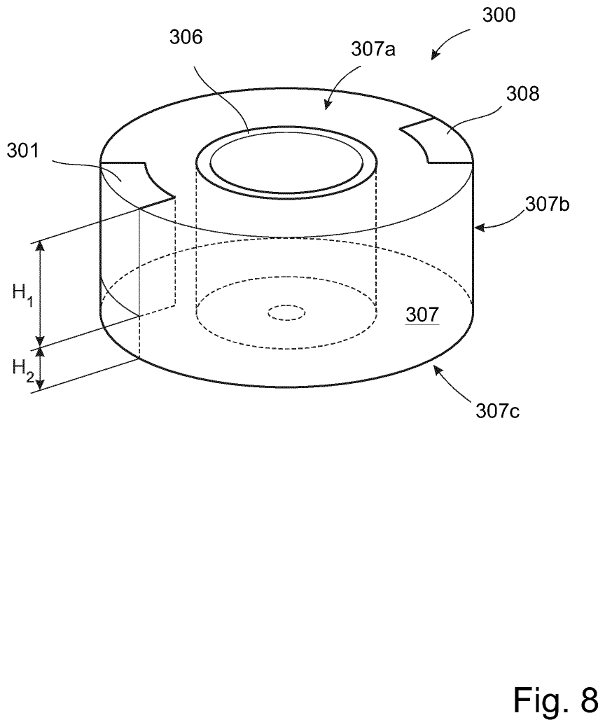

FIG. 8 illustrates a schematic perspective view of another example of the measuring unit 300. The measuring unit 300 comprises a measuring unit body 307 which for instance may comprise an electrically insulating material, a connector 306 for fixing the measuring unit 300 in direct electrical contact with a target member (not shown in FIG. 7) and a reference electrode 301 mounted to the measuring unit body 307 separated from and in electrical connection with the connector 306. The measuring unit body 307 comprises an upper annular surface 307a, a lower annular surface 307c and a cylindrical side surface 307b connecting the upper and lower surfaces 307a, 307c.

The example illustrated in FIG. 8 comprises an electrode member 308 mounted to the measuring unit body 307 separated from and in electrical connection with the connector 306 via a consumer assembly 303. An electromotive force is created by an electrolytic reaction between the connector 306 connected to the target member (not shown in FIG. 8) and in electrical connection with the electrode member 308 mounted to the measuring unit body 307 of the measuring unit 300 and where surrounding seawater is arranged to act as an electrolyte.

In the FIG. 8 example, the reference electrode 301 and the electrode member 308 are moulded into the measuring unit body 307 and extending from the upper surface 307a a distance H1 part of the way towards the lower surface 307c. The reference electrode 301 and the electrode member 308 terminate a distance H2 from the lower surface 307c.

Consequently, each one of the reference electrode 301 and the electrode member 308 has exposed surfaces at one end and along their outer surfaces which interrupt the cylindrical side surface 307b. When immersed, the reference electrode 301 and the electrode member 308 will be exposed to seawater on two sides. When mounted the lower ends of the reference electrode 301 and the electrode member 308 is inherently kept out of contact with the target member (not shown in FIG. 8).

The terminology used herein is for the purpose of describing particular aspects only and is not intended to be limiting of the disclosure. As used herein, the singular forms “a”, “an”, and “the” are intended to include the plural forms as well, unless the context clearly indicates otherwise. As used herein, the term “and/or” includes any and all combinations of one or more of the associated listed items. It will be further understood that the terms “comprises”, “comprising”, “includes” and/or “including” when used herein specify the presence of stated features, integers, actions, steps, operations, elements, and/or components, but do not preclude the presence or addition of one or more other features, integers, actions, steps, operations, elements, components, and/or groups thereof.

It will be understood that, although the terms first, second, etc., may be used herein to describe various elements, these elements should not be limited by these terms.

These terms are only used to distinguish one element from another. For example, a first element could be termed a second element, and, similarly, a second element could be termed a first element without departing from the scope of the present disclosure.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures. It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which this disclosure belongs. It will be further understood that terms used herein should be interpreted as having a meaning consistent with their meaning in the context of this specification and the relevant art and will not be interpreted in an idealized or overly formal sense unless expressly so defined herein.

It is to be understood that the present disclosure is not limited to the aspects described above and illustrated in the drawings; rather, the skilled person will recognize that many changes and modifications may be made within the scope of the present disclosure and appended claims. In the drawings and specification, there have been disclosed aspects for purposes of illustration only and not for purposes of limitation, the scope of the disclosure being set forth in the following claims.

1. A measuring unit for a target member adapted to be submerged into a body of water said measuring unit comprising:
a connector adapted to be in electrically conducting contact with said target member, at least a portion of said connector being in fluid communication with the environment ambient of said measuring unit
a reference electrode at least a portion of which being in fluid communication with the environment ambient of said measuring unit;
a voltmeter electrically connected to each one of said connector and said reference electrode whereby said voltmeter is adapted to determine a potential difference value indicative of a potential difference between said connector and said reference electrode and
a consumer assembly adapted to consume electric energy,
said measuring unit further comprising an electrode member at least a portion of said electrode member being in fluid communication with the environment ambient of said measuring unit, each one of said connector and said electrode member being electrically connected to said consumer assembly.

2. The measuring unit according to claim 1, wherein said electrode member is such that when said connector is in electrically conducting contact with said target member and when said target member and said measuring unit are submerged into a body of water said target member and said electrode member form a galvanic cell feeding electric energy to said consumer assembly.

3. The measuring unit according to claim 1, wherein said electrode member has an open circuit potential being more electropositive than a mixed potential of said target member and said connector when said connector is in electrically conducting contact with said target member

4. The measuring unit according to claim 1, wherein said electrode member has an open circuit potential being more electropositive than −0.5 V relative an electrode that is based on the reaction between elemental mercury and mercury chloride.

5. The measuring unit according to claim 1, further comprising a transmitter connected to said voltmeter, said transmitter being adapted to wirelessly transmit information relating to said potential difference value to a position outside said measuring unit, preferably said transmitter forms part of said consumer assembly.

6. The measuring unit according to claim 1, further comprising a battery forming part of said consumer assembly, each one of said connector and said electrode member being electrically connected to said battery

7. The measuring unit according to claim 5, wherein said battery is adapted to be connected to said transmitter

8. The measuring unit according claim 1, wherein said connector comprises, a metal or a metal alloy.

9. The measuring unit according to claim 1, wherein said reference electrode comprises, one of the following:
zinc, a zinc alloy, silver and silver chloride.

10. The measuring unit according to claim 1, wherein said electrode member comprises, copper or a copper alloy.

11. The measuring unit according to claim 1, wherein said measuring unit comprises a set of additional electrode members comprising at least one additional electrode member, at least a portion of each additional electrode member in said set of additional electrode members being in fluid communication with the environment ambient of said measuring unit

12. The measuring unit according to claim 11, wherein each additional electrode member in said set of additional electrode members is connected in series with said electrode member and said connector

13. The measuring unit according to claim 12, wherein each additional electrode member in said set of additional electrode members is such that when said connector is in electrically conducting contact with said target member and when said target member and said measuring unit are submerged into a body of water said target member and said additional electrode member form a galvanic cell feeding electric energy to said consumer assembly.

14. The measuring unit according to claim 11, wherein each additional electrode member in said set of additional electrode members has an open circuit potential being more electropositive than a mixed potential of said target member and said connector when said connector is in electrically conducting contact with said target member

15. The measuring unit according to claim 11, wherein each additional electrode member in said set of additional electrode members has an open circuit potential being more electropositive than −0.5 V relative an electrode that is based on the reaction between elemental mercury and mercury chloride.

16. The measuring unit according to claim 1, wherein said measuring unit comprises a measuring unit body accommodating at least each one of said connector, said reference electrode said voltmeter and said electrode member, preferably said measuring unit body being of a material having lower electric conductivity that at least each one of said connector, said reference electrode and said electrode member.

17. The measuring unit according to claim 1, wherein said connector comprises a connector portion adapted to be in direct contact with said target member

18. An assembly comprising a target member adapted to be submerged into a body of water and a measuring unit according to any claim 1, wherein said connector is in electrically conducting contact with said target member preferably said measuring unit being fixedly connected to said target member via said connector.

19. The assembly according to claim 18, wherein said connector portion is in direct contact with said target member

20. The assembly according to claim 18, wherein said target member is in electrically conducting contact with a sacrificial anode for corrosion protection of said target member, said wherein said connector is in electrically conducting contact with said target member at a position at a distance from said sacrificial anode

21. A marine vessel comprising the assembly according to claim 18.

22. The marine vessel according to claim 21, wherein said marine vessel comprises a monitoring unit adapted to receive measurement data from said transmitter

23. The marine vessel according to claim 22, wherein said monitoring unit is adapted to issue a warning signal in response to detecting that said information relating to said potential difference value is outside a predetermined range.

24. Use of a measuring unit for measuring a galvanic potential value indicative of a galvanic potential of a target member adapted to be submerged into a body of water, said measuring unit comprising:
a connector adapted to be in electrically conducting contact with said target member at least a portion of said connector being in fluid communication with the environment ambient of said measuring unit
a reference electrode at least a portion of which being in fluid communication with the environment ambient of said measuring unit;
a voltmeter electrically connected to each one of said connector and said reference electrode whereby said voltmeter is adapted to determine a potential difference value indicative of a potential difference between said connector and said reference electrode, and
a consumer assembly adapted to consume electric energy,
said measuring unit further comprising an electrode member at least a portion of said electrode member being in fluid communication with the environment ambient of said measuring unit, each one of said connector and said electrode member being electrically connected to said consumer assembly
